(19) United States
(12) Patent Application Publication
(10) Pub. No.: US 2024/0234444 A1
(43) Pub. Date: Jul. 11, 2024

(54) ELECTRONIC DEVICE

(71) Applicant: InnoLux Corporation, Miao-Li County (TW)

(72) Inventors: Hong-Sheng HSIEH, Miao-Li County (TW); Yu-Cheng HSIAO, Miao-Li County (TW)

(73) Assignee: InnoLux Corporation, Miao-Li County (TW)

(21) Appl. No.: 18/391,586

(22) Filed: Dec. 20, 2023

(30) Foreign Application Priority Data
Jan. 9, 2023 (CN) 202310026942.6

(51) Int. Cl. H01L 27/12; G02F 1/1335

(52) U.S. Cl. CPC H01L 27/1248; G02F 1/133502; G02F 1/1368

(57) ABSTRACT

An electronic device includes a substrate and a driving element disposed on the substrate. The driving element includes a refractive index matching structure, and the refractive index matching structure includes a first layer, a second layer and a first refractive index matching layer. The first refractive index matching layer is disposed between the first layer and the second layer, and a refractive index of the first refractive index matching layer is in a range between a refractive index of the first layer and a refractive index of the second layer.

### BACKGROUND OF THE DISCLOSURE

### 1. Field of the Disclosure

The present disclosure relates to an electronic device, and more particularly to an electronic device including refractive index matching layer.

### 2. Description of the Prior Art

In general display devices, since the layers of the display devices may have different refractive indices, thin film interference of light may occur at the interface between the layers, thereby affecting the display effect. Therefore, to reduce the reflectivity of the display devices through thin film interference is one of the important issues in the present field.

### SUMMARY OF THE DISCLOSURE

One of the purposes of the present disclosure is to provide an electronic device to solve the above-mentioned technical problem.

In some embodiments, an electronic device is provided by the present disclosure. The electronic device includes a substrate and a driving element disposed on the substrate. The driving element includes a refractive index matching structure, and the refractive index matching structure includes a first layer, a second layer and a first refractive index matching layer. The first refractive index matching layer is disposed between the first layer and the second layer, and a refractive index of the first refractive index matching layer is in a range between a refractive index of the first layer and a refractive index of the second layer.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 schematically illustrates a cross-sectional view of an electronic device according to a first embodiment of the present disclosure.

FIG. 2 schematically illustrates a cross-sectional view of an electronic device according to a second embodiment of the present disclosure.

FIG. 3 schematically illustrates a cross-sectional view of an electronic device according to a third embodiment of the present disclosure.

FIG. 4 schematically illustrates a cross-sectional view of an electronic device according to a fourth embodiment of the present disclosure.

FIG. 5 schematically illustrates a cross-sectional view of an electronic device according to a fifth embodiment of the present disclosure.

FIG. 6 schematically illustrates a cross-sectional view of an electronic device according to a sixth embodiment of the present disclosure.

FIG. 7 schematically illustrates a cross-sectional view of an electronic device according to a seventh embodiment of the present disclosure.

FIG. 8 schematically illustrates a cross-sectional view of an electronic device according to an eighth embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the device, and certain elements in various drawings may not be drawn to scale. In addition, the number and dimension of each element shown in drawings are only illustrative and are not intended to limit the scope of the present disclosure.

Certain terms are used throughout the description and following claims to refer to particular elements. As one skilled in the art will understand, electronic equipment manufacturers may refer to an element by different names. This document does not intend to distinguish between elements that differ in name but not function.

In the following description and in the claims, the terms “include”, “comprise” and “have” are used in an open-ended fashion, and thus should be interpreted to mean “include, but not limited to . . . ”

It will be understood that when an element or layer is referred to as being “disposed on” or “connected to” another element or layer, it can be directly on or directly connected to the other element or layer, or intervening elements or layers may be presented (indirectly). In contrast, when an element is referred to as being “directly on” or “directly connected to” another element or layer, there are no intervening elements or layers presented. When an element or a layer is referred to as being “electrically connected” to another element or layer, it can be a direct electrical connection or an indirect electrical connection. The electrical connection or coupling described in the present disclosure may refer to a direct connection or an indirect connection. In the case of a direct connection, the ends of the elements on two circuits are directly connected or connected to each other by a conductor segment. In the case of an indirect connection, switches, diodes, capacitors, inductors, resistors, other suitable elements or combinations of the above elements may be included between the ends of the elements on two circuits, but not limited thereto.

Although terms such as first, second, third, etc., may be used to describe diverse constituent elements, such constituent elements are not limited by the terms. The terms are used only to discriminate a constituent element from other constituent elements in the specification. The claims may not use the same terms, but instead may use the terms first, second, third, etc. with respect to the order in which an element is claimed. Accordingly, in the following description, a first constituent element may be a second constituent element in a claim.

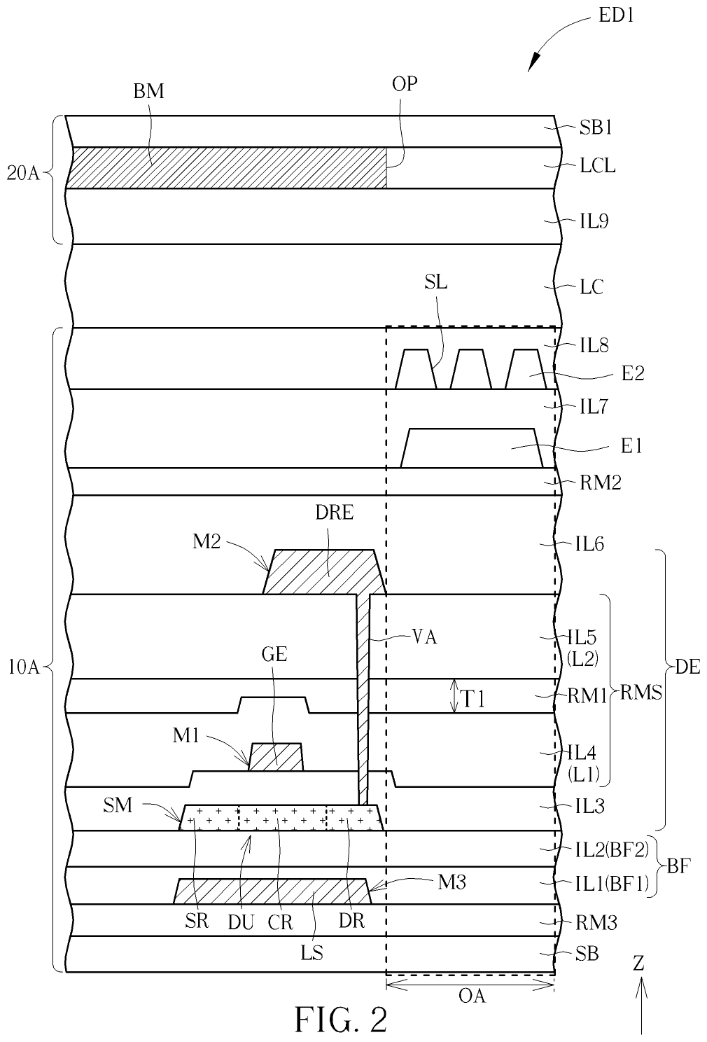

According to the present disclosure, the thickness, length and width may be measured through optical microscope, and the thickness or width may be measured through the cross-sectional view in the electron microscope, but not limited thereto. In some embodiments, the thickness of a layer can be measured in a cross-sectional view of the electronic device in a thickness direction Z of the substrate. In some embodiments, the thickness of a layer can be measured at a position in an opening area OA in a cross-sectional view of an array substrate 10A in a thickness direction Z of the substrate, as shown in FIG. 2. In some embodiments, the thickness of a layer can be measured at a position outside the opening area OA, and the present disclosure is not limited thereto.

In addition, any two values or directions used for comparison may have certain errors. In addition, the terms “equal to”, “equal”, “the same”, “approximately” or “substantially” are generally interpreted as being within +20%, +10%, +5%, +3%, +2%, +1%, or +0.5% of the given value.

In addition, the terms “the given range is from a first value to a second value” or “the given range is located between a first value and a second value” represents that the given range includes the first value, the second value and other values there between.

If a first direction is said to be perpendicular to a second direction, the included angle between the first direction and the second direction may be located between 80 to 100 degrees. If a first direction is said to be parallel to a second direction, the included angle between the first direction and the second direction may be located between 0 to 10 degrees.

Unless it is additionally defined, all terms (including technical and scientific terms) used herein have the same meaning as commonly understood by those ordinary skilled in the art. It can be understood that these terms that are defined in commonly used dictionaries should be interpreted as having meanings consistent with the relevant art and the background or content of the present disclosure, and should not be interpreted in an idealized or overly formal manner, unless it is specifically defined in the embodiments of the present disclosure.

It should be noted that the technical features in different embodiments described in the following can be replaced, recombined, or mixed with one another to constitute another embodiment without departing from the spirit of the present disclosure.

The electronic device of the present disclosure may include a display device, a sensing device, a back-light device, an antenna device, a tiled device or other electronic devices applied to the above-mentioned devices, but not limited thereto. The electronic device may be a foldable electronic device, a flexible electronic device or a stretchable electronic device. The display device may for example include laptops, common displays, tiled displays, vehicle displays, touch displays, televisions, monitors, smart phones, tablets, light source modules, lighting devices or electronic devices applied to the products mentioned above, but not limited thereto. The display device may be a liquid crystal display device, an organic light emitting diode display device or an inorganic light emitting diode display device. The inorganic light emitting diode display device may be a mini light emitting diode display device, a micro light emitting diode display device or a quantum dot light emitting diode display device. The display device may for example include light emitting diodes, fluorescent material, phosphor material, other suitable display mediums or combinations of the above-mentioned materials, but not limited thereto. The light emitting diode may for example include organic light emitting diode or inorganic light emitting diode. The inorganic light emitting diode may for example include mini light emitting diode, micro light emitting diode, quantum dot light emitting diode, other suitable materials or combinations of the above-mentioned materials, but not limited thereto. The sensing device may for example include a biosensor, a touch sensor, a fingerprint sensor, other suitable sensors or combinations of the above-mentioned sensors. The antenna device may for example include a liquid crystal antenna device, but not limited thereto. The tiled device may for example include a tiled display device or a tiled antenna device, but not limited thereto. The outline of the electronic device may be a rectangle, a circle, a polygon, a shape with curved edge or other suitable shapes. It should be noted that the electronic device of the present disclosure may be combinations of the above-mentioned devices, but not limited thereto. The display device or the electronic device applied to the display device is taking as an example of the electronic device to describe the contents of the present disclosure in the following, but the present disclosure is not limited thereto.

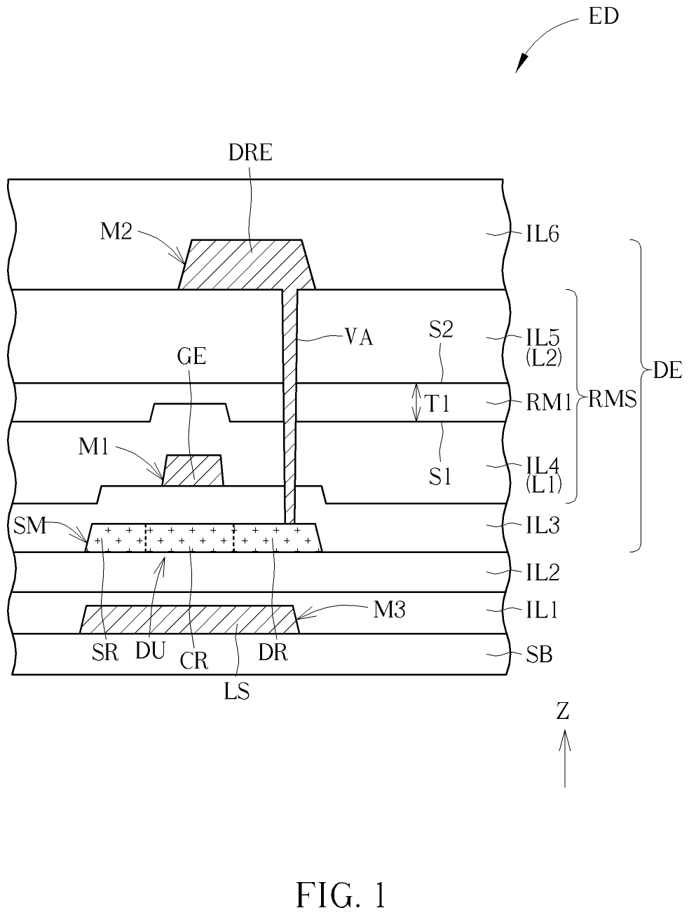

Referring to FIG. 1, FIG. 1 schematically illustrates a cross-sectional view of an electronic device according to a first embodiment of the present disclosure. According to the present embodiment, the electronic device ED may include a substrate SB and a driving element DE disposed on the substrate SB, wherein the driving element DE may include a refractive index matching structure RMS. In the present embodiment, the refractive index matching structure RMS may include a first layer L1, a second layer L2 and a first refractive index matching layer RM1, wherein the first refractive index matching layer RM1 is disposed between the first layer L1 and the second layer L2, and a refractive index of the first refractive index matching layer RM1 may be in a range between a refractive index of the first layer L1 and a refractive index of the second layer L2. The electronic device ED of the present embodiment may for example be a driving substrate, wherein the driving substrate may be applied to various kinds of device, such as display device, but not limited thereto. The display device may include a self-emissive display device and a non-self-emissive display device. In other embodiments, the electronic device ED may include any suitable structure according to the demands of the design of the product. The structure of the electronic device ED of the present embodiment will be detailed in the following.

The substrate SB may include a rigid substrate or a flexible substrate, but not limited thereto. The rigid substrate for example includes glass, quartz, sapphire, ceramic, other suitable materials or combinations of the above-mentioned materials. The flexible substrate for example includes polyimide (PI), polycarbonate (PC), polyethylene terephthalate (PET), other suitable materials or combinations of the above-mentioned materials. It should be noted that the substrate SB including a single-layer structure shown in FIG. 1 is exemplary, and the present disclosure is not limited thereto. In some embodiments, the substrate SB may include a multi-layer structure.

As shown in FIG. 1, the driving element DE of the present embodiment may include a semiconductor layer SM, an insulating layer IL3, a first conductive layer M1, an insulating layer IL4, a first refractive index matching layer RM1, an insulating layer IL5, and a second conductive layer M2, but not limited thereto. In other embodiments, the driving element DE may include other suitable structures according to the designs of the electronic device ED. In addition, the electronic device ED may further include an insulating layer IL1 and an insulating layer IL2 disposed between the substrate SB and the driving element DE, but not limited thereto. In detail, the insulating layer IL1 may be disposed on the substrate SB, the insulating layer IL2 may be disposed on the insulating layer IL1, the semiconductor layer SM may be disposed on the insulating layer IL2, the insulating layer IL3 may be disposed on the insulating layer IL2 and cover the semiconductor layer SM, the first conductive layer M1 may be disposed on the insulating layer IL3, the insulating layer IL4 may be disposed on the insulating layer IL3 and cover the first conductive layer M1, the first refractive index matching layer RM1 may be disposed on the insulating layer IL4, the insulating layer IL5 may be disposed on the first refractive index matching layer RM1, and the second conductive layer M2 may be disposed on the insulating layer IL5, but not limited thereto. The driving element DE shown in FIG. 1 may be a top gate transistor, but it is just an example. The driving element DE may also include a bottom gate transistor or other types of transistor, and it is not limited in the present embodiment.

In addition, the electronic device ED may further include an insulating layer IL6 disposed on the second conductive layer M2, wherein the insulating layer IL6 may be disposed on the insulating layer IL5 and cover the second conductive layer M2. The insulating layer IL6 may serve as the planarization layer to facilitate disposition of other elements and/or layers on the driving element DE.

As shown in FIG. 1, the first conductive layer M1 and the second conductive layer M2 may include any suitable conductive material, such as metal materials (for example, copper, titanium, aluminum, nickel, or combination thereof), but not limited thereto. The insulating layer IL1, the insulating layer IL2, the insulating layer IL3, the insulating layer IL4, the insulating layer IL5 and the insulating layer IL6 may include any suitable insulating material, such as silicon oxide, silicon nitride, silicon oxynitride, or combination thereof. According to some embodiments, the insulating layer IL1, the insulating layer IL2, the insulating layer IL3, the insulating layer IL4, and the insulating layer IL5 may include inorganic insulating materials, and the insulating layer IL6 may include organic insulating materials. The materials of the insulating layer IL1, the insulating layer IL2, the insulating layer IL3, the insulating layer IL4, the insulating layer IL5 and the insulating layer IL6 may be the same or different. As shown in FIG. 1, the first layer L1 and the second layer L2 of the refractive index matching structure RMS may include different inorganic materials. For example, the first layer L1 may include silicon nitride, and the second layer L2 may include silicon oxide.

As shown in FIG. 1, the semiconductor layer SM may include semiconductor materials, wherein the semiconductor materials for example includes low temperature polysilicon (LTPS), low temperature polysilicon oxide (LTPO), amorphous silicon (a-Si), metal oxides, other suitable materials or combination of the above-mentioned materials, but not limited thereto. In some embodiments, metal oxides for example includes indium gallium zinc oxide (IGZO), indium zinc oxide (IZO), indium gallium zinc tin oxide (IGZO), organic semiconductors including polycyclic aromatic compounds, or combinations of the above-mentioned materials. In some embodiments, the semiconductor material may include but not limited to amorphous silicon, polysilicon, germanium, compound semiconductors (such as gallium nitride, silicon carbide, gallium arsenide, gallium phosphide, indium indium and/or indium phosphide, arsenide antimonide), alloy semiconductors (such as silicon-germanium (SiGe) alloy, gallium-arsenic-phosphorus (GaAsP) alloy, aluminum-indium-arsenic (AlInAs) alloy, aluminum-gallium-arsenic (AlGaAs) alloy, gallium-indium-arsenic (Ga InAs) alloy, gallium-indium-phosphorus (GaInP) alloy or gallium-indium-arsenic-phosphorus (GaInAsP) alloy), or combination of the above-mentioned materials. In the present embodiment, the insulating layer IL1 and the insulating layer IL2 disposed between the substrate SB and the semiconductor layer SM may serve as buffer layers, and the insulating layer IL4 and the insulating layer IL5 may be the intermediate dielectric layers disposed between the first conductive layer M1 and the second conductive layer M2.

In the present embodiment, the driving element DE may include at least one driving unit DU, wherein the driving unit DU may include a transistor. The driving unit DU of the present embodiment may for example include a top gate transistor, but not limited thereto. In some embodiments, when the electronic device ED is applied to a display device, the driving unit DU may be used to drive the pixels in the display device, for example, the driving unit DU may drive the light emitting unit or provide a voltage to the pixel electrode. In some embodiments, when the electronic device ED is applied to a sensing device, the driving unit DU may be used to drive the sensing unit in the sensing device. Specifically, the driving unit DU may include a gate electrode GE, a source electrode (not shown), a drain electrode DRE and a semiconductor layer SM, wherein the gate electrode GE may be formed of the first conductive layer M1, and the source electrode and the drain electrode DRE may be formed of the second conductive layer M2, but not limited thereto. It should be noted that the drain electrode DRE shown in FIG. 1 may be the source electrode while another portion of the second conductive layer M2 serves as the drain. In other words, the first conductive layer M1 of the driving element DE may include the gate electrode GE, and the second conductive layer M2 of the driving element DE may include the source electrode and the drain electrode DRE, but not limited thereto. The semiconductor layer SM may include a source region SR, a drain region DR and a channel region CR connected between the source region SR and the drain region DR, wherein the channel region CR may at least partially overlap the gate electrode GE in the top view direction of the electronic device ED (that is, parallel to the direction z). The semiconductor layer SM of the present embodiment may for example include low temperature polysilicon, but not limited thereto. The drain electrode DRE may be electrically connected to the drain region DR through a via VA penetrating the insulating layer IL3, the insulating layer IL4, the first refractive index matching layer RM1 and the insulating layer IL5, but not limited thereto. Similarly, the source electrode (not shown) may be electrically connected to the source region SR. In addition, the driving unit DU may further include a gate insulating layer disposed between the gate electrode GE and the semiconductor layer SM, that is, the insulating layer IL3.

As shown in FIG. 1, in some embodiments, the electronic device ED may optionally include a third conductive layer M3 disposed on the substrate SB, wherein the third conductive layer M3 may form the light shielding element LS, but not limited thereto. The light shielding element LS may be used to block the light from the outside of the electronic device ED, thereby reducing the influence of the light on the electronic elements of the electronic device ED. The light shielding element LS may for example overlap at least a portion of the semiconductor layer SM, but not limited thereto.

According to the present embodiment, the driving element DE may include the refractive index matching structure RMS, the refractive index matching structure RMS may include a structure formed by sequentially stacking the first layer L1, the first refractive index matching layer RM1 and the second layer L2 on the substrate SB from bottom to top, wherein the first layer L1 and the second layer L2 may respectively contact the bottom surface S1 and the top surface S2 of the first refractive index matching layer RM1. In the present embodiment, the first refractive index matching layer RM1 is disposed between the insulating layer IL4 and the insulating layer IL5. Therefore, the insulating layer IL4 may be the first layer L1 of the refractive index matching structure RMS, and the insulating layer IL5 may be the second layer L2 of the refractive index matching structure RMS, but not limited thereto. In other embodiments, the first refractive index matching layer RM1 may be disposed at any suitable position in the driving element DE, and the two layers respectively contact the bottom surface S1 and the top surface S2 of the first refractive index matching layer RM1 may be regarded as the first layer L1 and the second layer L2. Furthermore, in the present embodiment, the refractive index matching structure RMS may be disposed between the first conductive layer M1 and the second conductive layer M2, or the refractive index matching structure RMS may be disposed between the gate electrode GE and the drain electrode DRE (or the source electrode) of the driving unit DU, but not limited thereto.

According to the present embodiment, the refractive index of the first layer L1 and the refractive index of the second layer L2 may be different, and the refractive index of the first refractive index matching layer RM1 is in a range between the refractive index of the first layer L1 and the refractive index of the second layer L2. In some embodiments, the refractive index of the first layer L1 may be greater than the refractive index of the first refractive index matching layer RM1, and the refractive index of the first refractive index matching layer RM1 may be greater than the refractive index of the second layer L2. In some other embodiments, the refractive index of the second layer L2 may be greater than the refractive index of the first refractive index matching layer RM1, and the refractive index of the first refractive index matching layer RM1 may be greater than the refractive index of the first layer L1.

According to some embodiments, the first refractive index matching layer RM1 may include silicon oxynitride, silicon oxide, silicon nitride, magnesium fluoride, calcium fluoride, barium fluoride, lanthanum fluoride, or combination thereof, but not limited thereto. For example, the refractive index of silicon oxide (SiOₓ) may range from 1.46 to 1.60, the refractive index of silicon oxynitride (SiOₓN_{y}) may range from 1.60 to 1.80, the refractive index of silicon nitride (SiNₓ) may range from 1.80 to 2.00, the refractive index of magnesium fluoride (MgF₂) may range from 1.30 to 1.40, the refractive index of barium fluoride (BaF₂) may range from 1.40 to 1.50, the refractive index of calcium fluoride (CaF₂) may range from 1.40 to 1.50, and the refractive index of lanthanum fluoride (LaF₃) may range from 1.55 to 1.65.

According to some embodiments, the first layer L1 may for example include silicon nitride, the second layer L2 may for example include silicon oxide, and the first refractive index matching layer RM1 may include the material with a refractive index in a range between the refractive index of silicon nitride and the refractive index of silicon oxide, such as silicon oxynitride, but not limited thereto. In other embodiments, when the first layer L1 and the second layer L2 include other materials, the first refractive index matching layer RM1 may include any suitable material having the refractive index in a range between the refractive index of the first layer L1 and the refractive index of the second layer L2.

According to the present disclosure, the first refractive index matching layer RM1 disposed in the driving element DE may reduce the ratio or probability of reflection of light at the interfaces between the layers of the driving element DE, thereby reducing the reflectivity of light in the electronic device ED. Specifically, since the refractive index of the first refractive index matching layer RM1 is in a range between the refractive index of the insulating layer IL4 and the refractive index of the insulating layer IL5, the refractive index difference between the insulating layer IL4 and the first refractive index matching layer RM1 and the refractive index difference between the insulating layer IL5 and the first refractive index matching layer RM1 may be lower than the refractive index difference between the insulating layer IL4 and the insulating layer IL5. Therefore, thin film interference of light may occur at the interfaces (that is, the interface between the first refractive index matching layer RM1 and the insulating layer IL4 and the interface between the first refractive index matching layer RM1 and the insulating layer IL5) by disposing the first refractive index matching layer RM1 in the electronic device ED. Therefore, the reflectivity of light of the electronic device may be reduced.

As shown in FIG. 1, the first refractive index matching layer RM1 may have a thickness T1, wherein the thickness T1 may be defined as the maximum thickness of the first refractive index matching layer RM1 in the thickness direction (that is, the direction Z) of the substrate SB in the cross-sectional view of the electronic device ED. According to some embodiments, in the thickness direction Z of the substrate SB, the thickness of the first refractive index matching layer RM1 measured at the position not overlapped with the semiconductor layer SM may be the thickness T1 of the first refractive index matching layer RM1. According to the present embodiment, the thickness T1 of the first refractive index matching layer RM1 may range from 200 angstrom (Å) to 6000 Å (that is, 200 Å≤ST1≤6000 Å), for example, range from 200 Å to 4000 Å, range from 200 Å to 3000 Å, range from 200 Å to 1500 Å, range from 300 Å to 1000 Å, or range from 2000 Å to 4000 Å, but not limited thereto. Through the design of thickness of the first refractive index matching layer RM1, the reflectivity of light of the electronic device ED may be reduced.

It should be noted that the electronic device ED of the present embodiment is not limited to what is shown in FIG. 1 and may include other suitable elements and/or layers. In some embodiments, the electronic device ED may further include other refractive index matching layers in addition to the first refractive index matching layer RM1 disposed between any two layers of the electronic device ED having refractive index difference.

Referring to FIG. 2, FIG. 2 schematically illustrates a cross-sectional view of an electronic device according to a second embodiment of the present disclosure. The electronic device ED1 of the present embodiment may include display device. The liquid crystal display device is taken as an example of the electronic device ED1 for describing the contents of the present embodiment in the following, but the present disclosure is not limited thereto.

As shown in FIG. 2, the electronic device ED1 includes an array substrate 10A, a color filter substrate 20A and a display medium layer LC. The display medium layer LC is disposed between the array substrate 10A and the color filter substrate 20A. The display medium layer LC may for example be a liquid crystal layer. The array substrate 10A mainly includes the substrate SB and the driving element DE mentioned above. In the array substrate 10A, the driving elements DE may be disposed on the substrate SB, and the driving elements DE may be arranged in an array. In addition to the elements and/or layers mentioned above, the array substrate 10A may further include an electrode E1 disposed on the insulating layer IL6, an insulating layer IL7 disposed on the insulating layer IL6 and covering the electrode E1, an electrode E2 disposed on the insulating layer IL7, and an insulating layer IL8 disposed on the insulating layer IL7 and covering the electrode E2. In addition, the electronic device ED1 may further include the display medium layer LC disposed on the insulating layer IL8, an insulating layer IL9 disposed on the display medium layer LC, a black matrix layer BM and a light converting layer LCL disposed on the insulating layer IL9, and a substrate SB1 disposed on the black matrix layer BM and the light converting layer LCL, but not limited thereto. In detail, the color filter substrate 20A includes the substrate SB1, the light converting layer LCL and the black matrix layer BM. The light converting layer LCL and the black matrix layer BM are disposed on the substrate SB1. The insulating layer IL9 is disposed on the light converting layer LCL and the black matrix layer BM. According to some embodiments, the light converting layer LCL may be a color filter layer. According to some embodiments, the insulating layer IL8 and the insulating layer IL9 may be alignment layers and may for example include polyimide (PI). According to some embodiments, the display medium layer LC may be a liquid crystal layer.

According to some embodiments, the thicknesses of the insulating layer IL3, the insulating layer IL4, the insulating layer IL5 and the insulating layer IL7 are not limited, and these thicknesses may range from 500 Å to 5000 Å, for example, range from 1000 Å to 3000 Å, or range from 1000 Å to 2500 Å. The thicknesses and materials of the insulating layer IL3, the insulating layer IL4, the insulating layer IL5 and the insulating layer IL7 may be the same or different from each other, it is not limited in the present disclosure. The insulating layer IL3, the insulating layer IL4, the insulating layer IL5 and the insulating layer IL7 may include inorganic insulating materials.

As shown in FIG. 2, the electrode E1 and the electrode E2 may include any suitable conductive material. For example, the electrode E1 and the electrode E2 may include transparent conductive materials, but not limited thereto. One of the electrode E1 and the electrode E2 may serve as the common electrode while another one of the electrode E1 and the electrode E2 may serve as the pixel electrode. According to some embodiments, the electrode E1 and/or the electrode E2 may have slits. For example, as shown in FIG. 2, the electrode E2 may be a patterned electrode and include at least one slit SL, but not limited thereto. According to some embodiments, the electrode E1 may be a patterned electrode and include at least one slit.

As shown in FIG. 2, the electrode E1 may be the pixel electrode, and the electrode E2 may be the common electrode in the present embodiment, but not limited thereto. Although it is not shown in the figure, when the electrode E1 is the pixel electrode, the electrode E1 may be disposed on the planarization layer IL6 and be electrically connected to the drain electrode DRE. In other embodiments, the electrode E1 and the electrode E2 may respectively be the common electrode and the pixel electrode. The electrode E1 and the electrode E2 may be transparent conductive layers and may for example include indium tin oxide (ITO). The display medium layer LC may include liquid crystal molecules, and the driving unit DU of the driving element DE may be electrically connected to the electrode E1 or the electrode E2 to control rotation of the liquid crystal molecules in the display medium layer LC. The black matrix layer BM may include a plurality of openings OP, and the light converting layer LCL may be disposed in the openings OP. The light converting layer LCL may include any material capable of adjusting wavelength or color of light, such as color filter, fluorescent, phosphor materials, quantum dots or other suitable materials. The material of the substrate SB1 may refer to the material of the substrate SB. The insulating layer IL7, the insulating layer IL8 and the insulating layer IL9 may include any suitable insulating material. It should be noted that although it is not shown in FIG. 2, the electronic device ED1 may further include a backlight module disposed at a side of the substrate SB opposite to the insulating layer IL1. That is, the substrate SB is disposed between the backlight module and the insulating layer IL1.

According to some embodiments, as shown in FIG. 2, the electronic device ED1 may optionally include a second refractive index matching layer RM2 disposed between the electrode E1 and the insulating layer IL6, but not limited thereto. According to some embodiments, the electrode E1 may be the pixel electrode, the insulating layer IL6 may be the planarization layer, and the second refractive index matching layer RM2 may be disposed between the planarization layer IL6 and the pixel electrode (that is, the electrode E1). The refractive index of the second refractive index matching layer RM2 may be in a range between the refractive index of the electrode E1 and the refractive index of the insulating layer IL6. As mentioned above, the insulating layer IL6 may serve as the planarization layer, and the electrode E1 may be the pixel electrode. Therefore, the electronic device ED1 may include the planarization layer disposed on the driving element DE and the pixel electrode disposed on the planarization layer, and the pixel electrode may be electrically connected to the driving element DE, for example, be electrically connected to the drain electrode DRE of the driving element DE, wherein the second refractive index matching layer RM2 may be disposed between the planarization layer and the pixel electrode, and the refractive index of the second refractive index matching layer RM2 may be in a range between the refractive index of the planarization layer and the refractive index of the pixel electrode.

According to some embodiments, the insulating layer IL6 may for example include organic photoresist, the electrode E1 may for example include indium tin oxide, and the second refractive index matching layer RM2 may include the materials having the refractive index in a range between the refractive index of the organic photoresist and the refractive index of indium tin oxide. For example, the second refractive index matching layer RM2 may include silicon oxynitride, but not limited thereto. The thickness of the insulating layer IL6 may range from 1 micrometer (μm) to 5 μm, for example, range from 2 μm to 3 μm. The thickness of the insulating layer IL6 may be greater than the thickness of the second refractive index matching layer RM2 and the thickness of the insulating layer IL5.

In other embodiments, the electrode E1 and the insulating layer IL6 may include other materials, and the material of the second refractive index matching layer RM2 may be determined according to the materials and refractive indices of the electrode E1 and the insulating layer IL6, such that the refractive index of the second refractive index matching layer RM2 is in a range between the refractive index of the electrode E1 and the refractive index of the insulating layer IL6. By disposing the second refractive index matching layer RM2 between the insulating layer IL6 and the electrode E1 having refractive index difference, the ratio or probability of reflection of light at the interfaces between the layers of the electronic device ED may be reduced. The material and thickness of the second refractive index matching layer RM2 may refer to the material and the thickness of the first refractive index matching layer RM1, and will not be redundantly described.

In some embodiments, as shown in FIG. 2, the thicknesses (for example, the thickness T1 of the first refractive index matching layer RM1 and the thickness of the second refractive index matching layer RM2) of the layers may be measured at the position in an opening area OA in the cross-sectional view of the array substrate 10A in the thickness direction Z of the substrate. As shown in FIG. 2, the opening area OA may be the area enclosed by dotted lines, that is, the measuring position may not overlap the semiconductor layer SM and the second conductive layer M2 of the driving element DE in the array substrate 10A. Similarly, the thicknesses of other layers may also be measured at a position corresponding to the opening area OA in the thickness direction Z of the substrate.

As shown in FIG. 2, the electronic device ED1 may include a buffer layer BF and a third refractive index matching layer RM3 disposed on the substrate SB. The buffer layer BF may be disposed between the third refractive index matching layer RM3 and the driving element DE, and the refractive index of the third refractive index matching layer RM3 may be in a range between the refractive index of the substrate SB and the refractive index of the buffer layer BF. The buffer layer BF may be a single-layer structure or a multi-layer structure. FIG. 2 shows that the buffer layer BF includes a multi-layer structure which includes a first buffer layer BF1 and a second buffer layer BF2, but not limited thereto. According to some embodiments, the first buffer layer BF1 may include silicon nitride, and the second buffer layer BF2 may include silicon oxide.

The first buffer layer BF1 may be the insulating layer IL1 mentioned above, and the second buffer layer BF2 may be the insulating layer IL2 mentioned above, and will not be redundantly described. The first buffer layer BF1 and the second buffer layer BF2 may respectively silicon oxide, silicon nitride, silicon oxynitride or combinations thereof. In the present embodiment, the first buffer layer BF1 may for example include silicon nitride, and the second buffer layer BF2 may for example include silicon oxide, but not limited thereto. The electronic device ED1 may optionally include a light shielding element LS disposed on the third refractive index matching layer RM3 and covered by the first buffer layer BF1, but not limited thereto. The materials of the first buffer layer BF1 and the second buffer layer BF2 may be the same or different.

According to some embodiments, the thickness of the first buffer layer BF1 may range from 200 Å to 6000 Å (that is, 200 Å≤Sthickness≤6000 Å), for example, range from 200 Å to 4000 Å, range from 200 Å to 3000 Å, range from 200 Å to 1500 Å, or range from 1000 Å to 3000 Å, but not limited thereto. The range of the thickness of the second buffer layer BF2 may substantially be the same as the thickness of the first buffer layer BF1, and will not be redundantly described. The thickness of the first buffer layer BF1 and the thickness of the second buffer layer BF2 may be the same or different. According to some embodiments, an electronic device may include the first buffer layer BF1 but not include the second buffer layer BF2, and the thickness of the first buffer layer BF1 may range from 3000 Å to 5000 Å. According to some embodiments, an electronic device may include the second buffer layer BF2 but not include the first buffer layer BF1, and the thickness of the second buffer layer BF2 may range from 3000 Å to 5000 Å.

According to the present embodiment, as shown in FIG. 2, the third refractive index matching layer RM3 may be disposed on the substrate SB, the first buffer layer BF1 may be disposed on the third refractive index matching layer RM3, and the second buffer layer BF2 may be disposed on the first buffer layer BF1. In other words, the first buffer layer BF1 and the second buffer layer BF2 may be disposed between the third refractive index matching layer RM3 and the driving element DE, and the third refractive index matching layer RM3 may be disposed between the substrate SB and the first buffer layer BF1. In the present embodiment, the refractive index of the third refractive index matching layer RM3 may be in a range between the refractive index of the substrate SB and the refractive index of the first buffer layer BF1. For example, the substrate SB may include glass, the first buffer layer BF1 may include silicon nitride, and the third refractive index matching layer RM3 may include the materials having the refractive index in a range between the refractive index of glass and the refractive index of silicon nitride, such as silicon oxynitride, but not limited thereto. In other embodiments, the substrate SB and the first buffer layer BF1 may include other materials, and the third refractive index matching layer RM3 may include any suitable material having the refractive index in a range between the refractive index of the material of the substrate SB and the refractive index of the material of the first buffer layer BF1. By disposing the third refractive index matching layer RM3 between the substrate SB and the first buffer layer BF1 having refractive index difference, the reflectively of the electronic device may be reduced through thin film interference. The material and thickness of the third refractive index matching layer RM3 may refer to the material and thickness of the first refractive index matching layer RM1 mentioned above, and will not be redundantly described.

It should be noted that the structure of the electronic device ED1 of the present embodiment is not limited to what is shown in FIG. 2. In some embodiments, the electronic device ED1 may include any one of the first refractive index matching layer RM1, the second refractive index matching layer RM2 and the third refractive index matching layer RM3. In some embodiments, the electronic device ED1 may include any two of the first refractive index matching layer RM1, the second refractive index matching layer RM2 and the third refractive index matching layer RM3. In some embodiments, the electronic device ED1 may include the first refractive index matching layer RM1, the second refractive index matching layer RM2 and the third refractive index matching layer RM3.

According to some embodiments, the first refractive index matching layer RM1, the second refractive index matching layer RM2 and the third refractive index matching layer RM3 may respectively include silicon oxynitride, silicon oxide, silicon nitride, magnesium fluoride, calcium fluoride, barium fluoride, lanthanum fluoride, or combination thereof, but not limited thereto. The materials of the first refractive index matching layer RM1, the second refractive index matching layer RM2 and the third refractive index matching layer RM3 may be the same or different.

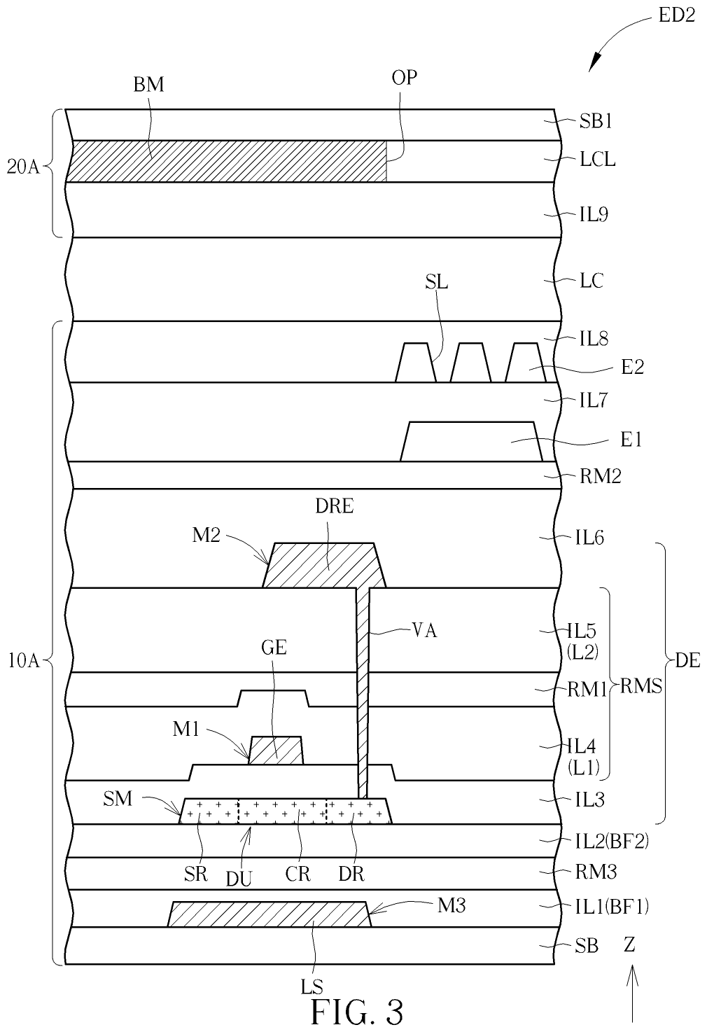

Referring to FIG. 3, FIG. 3 schematically illustrates a cross-sectional view of an electronic device according to a third embodiment of the present disclosure. The main difference between the structure shown in FIG. 3 and the structure shown in FIG. 2 is the design of the layers between the substrate SB and the semiconductor layer SM. The difference between FIG. 3 and FIG. 2 will be detailed in the following, and other structures in FIG. 3 may be similar to the structures in FIG. 2 and will not be redundantly described. According to the present embodiment, in the electronic device ED2, the first buffer layer BF1 (that is, the insulating layer IL1) is disposed on the substrate SB, the third refractive index matching layer RM3 is disposed on the first buffer layer BF1, and the second buffer layer BF2 (that is, the insulating layer IL2) is disposed on the third refractive index matching layer RM3 or disposed between the third refractive index matching layer RM3 and the driving element DE. In other words, the third refractive index matching layer RM3 may be disposed between the first buffer layer BF1 and the second buffer layer BF2.

In the present embodiment, as shown in FIG. 3, the refractive index of the third refractive index matching layer RM3 may be in a range between the refractive index of the first buffer layer BF1 and the refractive index of the second buffer layer BF2. For example, the second buffer layer BF2 may include silicon oxide, the first buffer layer BF1 may include silicon nitride, and the third refractive index matching layer RM3 may include the materials having the refractive index in a range between the refractive index of silicon oxide and the refractive index of silicon nitride, such as silicon oxynitride, but not limited thereto. In other embodiments, the first buffer layer BF1 and the second buffer layer BF2 may include other materials, and the third refractive index matching layer RM3 may include any suitable material having the refractive index in a range between the refractive index of the material of the first buffer layer BF1 and the refractive index of the material of the second buffer layer BF2. By disposing the third refractive index matching layer RM3 between the first buffer layer BF1 and the second buffer layer BF2 having refractive index difference, the reflectivity of the electronic device ED2 may be reduced.

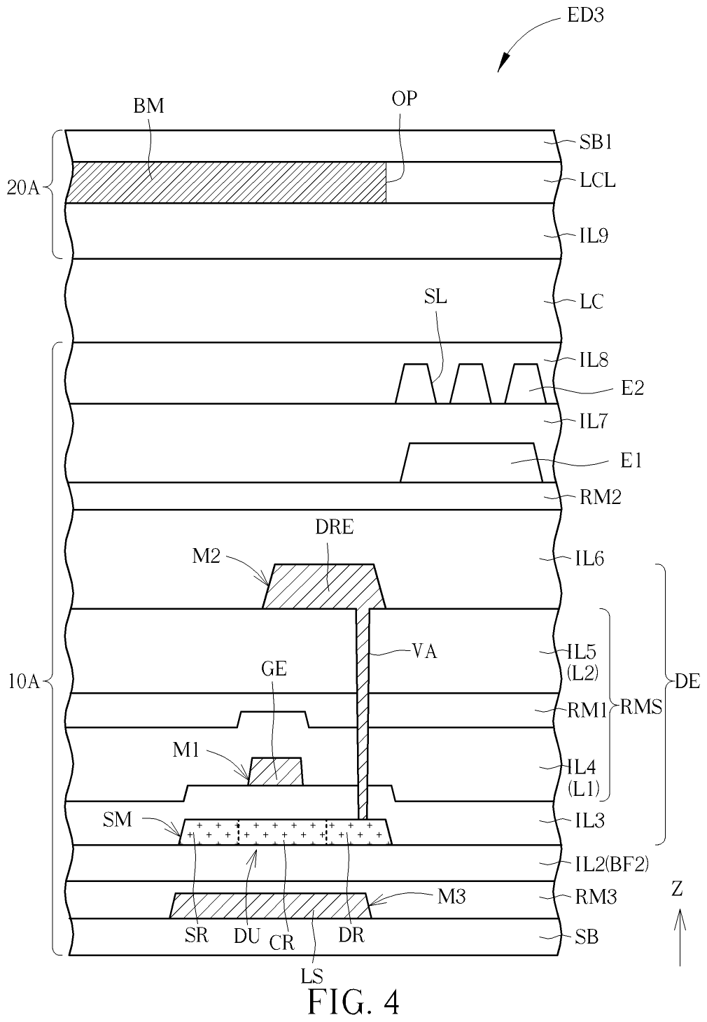

Referring to FIG. 4, FIG. 4 schematically illustrates a cross-sectional view of an electronic device according to a fourth embodiment of the present disclosure. The main difference between the structure shown in FIG. 4 and the structure shown in FIG. 2 is the design of the layers between the substrate SB and the semiconductor layer SM. The difference between FIG. 4 and FIG. 2 will be detailed in the following, and other structures in FIG. 4 may be similar to the structures in FIG. 2 and will not be redundantly described. According to the present embodiment, the electronic device ED3 may include the second buffer layer BF2 (that is, the insulating layer IL2) and the third refractive index matching layer RM3 disposed between the substrate SB and the driving element DE, wherein the third refractive index matching layer RM3 may be disposed on the substrate SB, and the second buffer layer BF2 may be disposed on the third refractive index matching layer RM3. In other words, the second buffer layer BF2 may be disposed between the third refractive index matching layer RM3 and the driving element DE, and the third refractive index matching layer RM3 may be disposed between the substrate SB and the second buffer layer BF2.

In the present embodiment, as shown in FIG. 4, the refractive index of the third refractive index matching layer RM3 may be in a range between the refractive index of the second buffer layer BF2 and the refractive index of the substrate SB. For example, the second buffer layer BF2 may include silicon oxide, the substrate SB may include glass, and the third refractive index matching layer RM3 may include the materials having the refractive index in a range between the refractive index of silicon oxide and the refractive index of glass, but not limited thereto. In other embodiments, the second buffer layer BF2 and the substrate SB may include other materials, and the third refractive index matching layer RM3 may include any suitable material having the refractive index in a range between the refractive index of the material of the second buffer layer BF2 and the refractive index of the material of the substrate SB.

Compared with the electronic device ED2 shown in FIG. 3, the electronic device ED3 of the present embodiment may not include the first buffer layer BF1 (that is, the insulating layer IL1), but not limited thereto. Specifically, when the refractive index difference between the material of the first buffer layer BF1 (as shown in FIG. 2) and the material of the substrate SB and/or the refractive index difference between the material of the first buffer layer BF1 and the material of the second buffer layer BF2 is great, the reflectivity of the electronic device ED3 may be reduced by making the electronic device ED3 not including the first buffer layer BF1. For example, the second buffer layer BF2 may include silicon oxide, the first buffer layer BF1 (as shown in FIG. 2) may include silicon nitride, and the substrate SB may include glass, wherein the refractive index difference between silicon nitride and silicon oxide and/or the refractive index difference between silicon nitride and glass may be great, but not limited thereto.

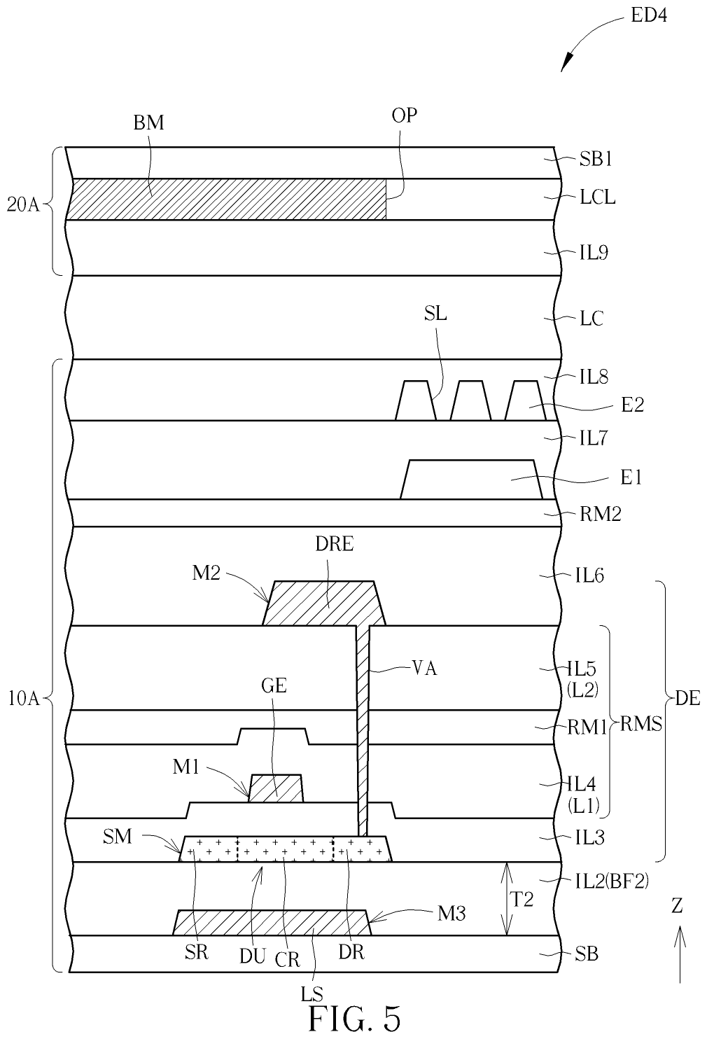

Referring to FIG. 5, FIG. 5 schematically illustrates a cross-sectional view of an electronic device according to a fifth embodiment of the present disclosure. The main difference between the structure shown in FIG. 5 and the structure shown in FIG. 2 is the design of the layers between the substrate SB and the semiconductor layer SM. The difference between FIG. 5 and FIG. 2 will be detailed in the following, and other structures in FIG. 5 may be similar to the structures in FIG. 2 and will not be redundantly described. According to the present embodiment, the electronic device ED4 may include the second buffer layer BF2 (that is, the insulating layer IL2) disposed between the substrate SB and the driving element DE, wherein the second buffer layer BF2 may directly contact the substrate SB. In other words, the electronic device ED4 may not include the first buffer layer BF1 (that is, the insulating layer IL1) and the third refractive index matching layer RM3 in the above-mentioned structure shown in FIG. 3. As mentioned above, by making the electronic device ED4 not including the first buffer layer BF1 whose refractive index is significantly different from the refractive index of the substrate SB and/or the refractive index of the second buffer layer BF2, the reflectivity of the electronic device ED4 may be reduced. In addition, a proper material may be selected to make the refractive index difference between the substrate SB and the second buffer layer BF2 lower. Therefore, the third refractive index matching layer RM3 may not be disposed between the substrate SB and the second buffer layer BF2, as shown in FIG. 5.

As shown in FIG. 5, the second buffer layer BF2 may have a thickness T2, wherein the thickness T2 may be defined as the maximum thickness of the second buffer layer BF2 in the thickness direction (that is, the direction Z) of the substrate SB in a cross-sectional view of the electronic device ED4. According to some embodiments, in the thickness direction Z of the substrate SB, the thickness of the second buffer layer BF2 measured at the position not overlapped with the semiconductor layer SM may be the thickness T2 of the second buffer layer BF2. According to the present embodiment, the thickness T2 of the second buffer layer BF2 may range from 200 to 6000 Å (that is, 200 Å≤T2≤6000 Å), for example, range from 200 to 4000 Å, range from 200 to 3000 Å, or range from 200 to 1500 Å, but not limited thereto. Through the proper design of the thickness of the second buffer layer BF2, the reflectivity of the electronic device ED4 may be effectively reduced.

According to some embodiments, as shown in FIG. 5, the first buffer layer BF1 and the third refractive index matching layer RM3 shown in FIG. 3 may not be disposed in the electronic device ED4. In FIG. 5, the thickness T2 of the second buffer layer BF2 may range from 2000 to 6000 Å, for example, range from 3000 to 6000 Å, or range from 3500 to 5000 Å, but not limited thereto. Therefore, even a single layer of the second buffer layer BF2 may provide the buffering effect. By making the thickness of the second buffer layer BF2 in the above-mentioned range, the probability that the buffering effect is affected may be reduced under the condition that the first buffer layer BF1 is removed. In some embodiments, the thickness T2 may be greater than the thickness of the second buffer layer BF2 shown in FIG. 2 or FIG. 3. In some embodiments, the thickness T2 may be designed as the sum of the thicknesses of the second buffer layer BF2 and the first buffer layer BF1 shown in FIG. 2 or FIG. 3. Through the above-mentioned designs of thickness, the reflectivity of the electronic device may be reduced through thin film interference under the condition that the influence on the buffering effect is reduced.

Table 1 shows the result of the measured reflectivity of the electronic devices of various examples and a comparative example by taking the structure in FIG. 2 as the main structure. The electronic device in the comparative example does not include the first refractive index matching layer RM1, the second refractive index matching layer RM2 and the third refractive index matching layer RM3. The electronic devices in the example 1, the example 2 and the example 3 respectively include the first refractive index matching layer RM1, the second refractive index matching layer RM2 and the third refractive index matching layer RM3. The electronic device in the example 4 includes the first refractive index matching layer RM1, the second refractive index matching layer RM2 and the third refractive index matching layer RM3.

TABLE 1

| | Comparative | Example | Example | Example | Example |
|---|---|---|---|---|---|
| | example 1 | 1 | 2 | 3 | 4 |
| RM1 | X | V | X | X | V |
| RM2 | X | X | V | X | V |
| RM3 | X | X | X | V | V |
| Reflectivity | 3.67 | <3 | <3 | <3 | <2 |
| (%) | | | | | |

“X” represents that the layer does not exist, “V” represents that the layer exists

In the present disclosure, the sum of the thicknesses of the insulating layer IL4 (the first layer L1), the first refractive index matching layer RM1 and the insulating layer IL5 (the second layer L2) may be controlled to be within a certain range to reduce the influence on the driving effect of the driving element DE. For example, the sum of the thicknesses of the insulating layer IL4 (the first layer L1), the first refractive index matching layer RM1 and the insulating layer IL5 (the second layer L2) may be controlled to be ranged from 3000 Å to 10000 Å, for example, range from 5000 Å to 8000 Å, or range from 7000 Å to 8000 Å.

According to the present disclosure, the reflectivity may for example be measured at the opening area of the electronic device. For example, the array substrate 10A shown in FIG. 2 may be the sample for measuring, and the measurement may be performed at the position in the opening area OA (the area enclosed by the dotted-line). “The opening area of the electronic device” described herein may for example be the area corresponding to the opening OP of the black matrix layer BM, or the area corresponding to the light converting layer LCL, or the area in which the driving element DE is not disposed. For example, in the array substrate 10A, the opening area is not overlapped with the semiconductor layer SM and the second conductive layer M2 of the driving element DE. For example, the opening area of the electronic device may be the opening area OA shown in FIG. 2, but not limited thereto. In other words, the opening area of the electronic device may be the light output area of the electronic device. Specifically, the reflectivity shown in FIG. 1 may be the integral of the reflectivity of light with the wavelength in the visible light wavelength range (for example, the wavelength from 380 nanometers (nm) to 780 nm) measured in the opening area OA of the array substrate 10A through any suitable equipment, but not limited thereto.

In the comparative example, the reflectivity of light in the electronic device is 3.67%. In the embodiments of the present disclosure, the reflectivity may respectively be lower than 3% and lower than 2%, which is lower than the reflectivity (3.67%) of light in the electronic device in the comparative example. It can be seen from table 1 that the reflectivity of light in the electronic device may be reduced by disposing refractive index matching layer (s) in the electronic device, thereby improving the display effect of the electronic device. The refractive index matching layer (s) may for example include the first refractive index matching layer RM1, the second refractive index matching layer RM2, the third refractive index matching layer RM3 or combinations thereof.

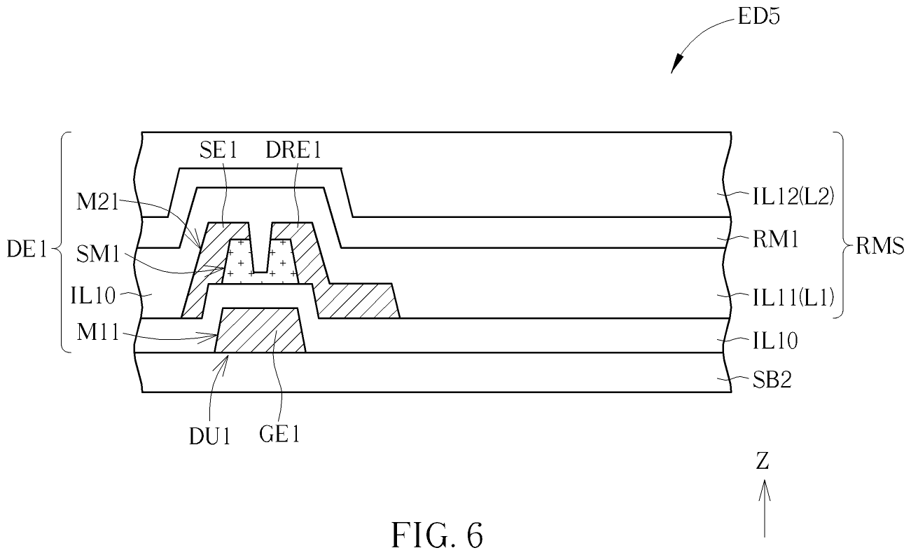

Referring to FIG. 6, FIG. 6 schematically illustrates a cross-sectional view of an electronic device according to a sixth embodiment of the present disclosure. The electronic device ED5 of the present embodiment may for example be the driving substrate, wherein the driving substrate may be applied to various kinds of device, such as display device, but not limited thereto. According to the present embodiment, the electronic device ED5 may include a substrate SB2 and a driving element DE1 disposed on the substrate SB2, wherein the driving element DE1 may include the refractive index matching structure RMS. The material of the substrate SB2 may refer to the material of the substrate SB mentioned above. The driving element DE1 may include a first conductive layer M11, an insulating layer IL10, a second conductive layer M21, a semiconductor layer SM1, an insulating layer IL11, the first refractive index matching layer RM1, and an insulating layer IL12, but not limited thereto. In other embodiments, the driving element DE1 may include other suitable structures according to the design of the electronic device ED5. The first conductive layer M11 may be disposed on the substrate SB2, the insulating layer IL10 may be disposed on the substrate SB2 and cover the first conductive layer M11, the semiconductor layer SM1 may be disposed on the insulating layer IL10, the second conductive layer M21 may be disposed on the insulating layer IL10 and cover the semiconductor layer SM1, the insulating layer IL11 may be disposed on the second conductive layer M21, the first refractive index matching layer RM1 may be disposed on the insulating layer IL11, and the insulating layer IL12 may be disposed on the first refractive index matching layer RM1, but not limited thereto. The materials of the first conductive layer M11 and the second conductive layer M21 may refer to the materials of the first conductive layer M1 and the second conductive layer M2 mentioned above. The insulating layer IL10, the insulating layer IL11 and the insulating layer IL12 may include any suitable insulating material. The material of the semiconductor layer SM1 may refer to the material of the semiconductor layer SM mentioned above. For example, the semiconductor layer SM1 of the present embodiment may include amorphous silicon, but not limited thereto. The driving element DE1 may include at least one driving unit DU1, wherein the driving unit DU1 may for example be a bottom gate thin film transistor and include a gate electrode GE1, a source electrode SE1, a drain electrode DRE1 and a semiconductor layer SM1, but not limited thereto. The gate electrode GE1 may be formed of the first conductive layer M11, and the source electrode SE1 and the drain electrode DRE1 may be formed of the second conductive layer M21 and contact the semiconductor layer SM1. In other words, the first conductive layer M11 of the driving element DE1 may include the gate electrode GE1, and the second conductive layer M21 of the driving element DE1 may include the source electrode SE1 and the drain electrode DRE1, but not limited thereto. In addition, the driving unit DU1 may further include a gate insulating layer disposed between the gate electrode GE1 and the semiconductor layer SM1, that is, the insulating layer IL10. In addition, the insulating layer IL12 may serve as the planarization layer, such that other elements and/or layers may be disposed on the driving element DE1, but not limited thereto.

According to the present embodiment, the driving element DE1 may include the refractive index matching structure RMS, and the refractive index matching structure RMS may include the first layer L1, the second layer L2 and the first refractive index matching layer RM1 disposed between the first layer L1 and the second layer L2. The detail of the features of the first layer L1, the second layer L2 and the first refractive index matching layer RM1 may refer to the contents mentioned above, and will not be redundantly described. As shown in FIG. 6, the first refractive index matching layer RM1 of the present embodiment is disposed between the insulating layer IL11 and the insulating layer IL12, and therefore, the insulating layer IL11 may be the first layer L1 of the refractive index matching structure RMS, and the insulating layer IL12 may be the second layer L2 of the refractive index matching structure RMS, but not limited thereto. In other embodiments, the first refractive index matching layer RM1 may be disposed at any suitable position in the driving element DE1. As shown in FIG. 6, in the present embodiment, the second conductive layer M21 may be disposed on the first conductive layer M11, and the refractive index matching structure RMS may be disposed on the second conductive layer M21, but not limited thereto.

Similar to the embodiments mentioned above, as shown in FIG. 6, the refractive index matching structure RMS may include the first layer L1, the second layer L2 and the first refractive index matching layer RM1, the first refractive index matching layer RM1 is disposed between the first layer L1 and the second layer L2, and the refractive index of the first refractive index matching layer RM1 is in a range between the refractive index of the first layer L1 (that is, the insulating layer IL11) and the refractive index of the second layer L2 (that is, the insulating layer IL12). For example, the first layer L1 may include silicon nitride, the second layer L2 may include organic photoresist, and the first refractive index matching layer RM1 may include any suitable material having the refractive index in a range between the refractive index of silicon nitride and the refractive index of organic photoresist, such as silicon oxynitride, but not limited thereto. In other embodiments, the first layer L1 and the second layer L2 may include other materials, and the first refractive index matching layer RM1 may include any suitable material having the refractive index in a range between the refractive index of the first layer L1 and the refractive index of the second layer L2. By disposing the first refractive index matching layer RM1 between the first layer L1 and the second layer L2 having refractive index difference, the probability of reflection of light in the driving element DE1 may be reduced.

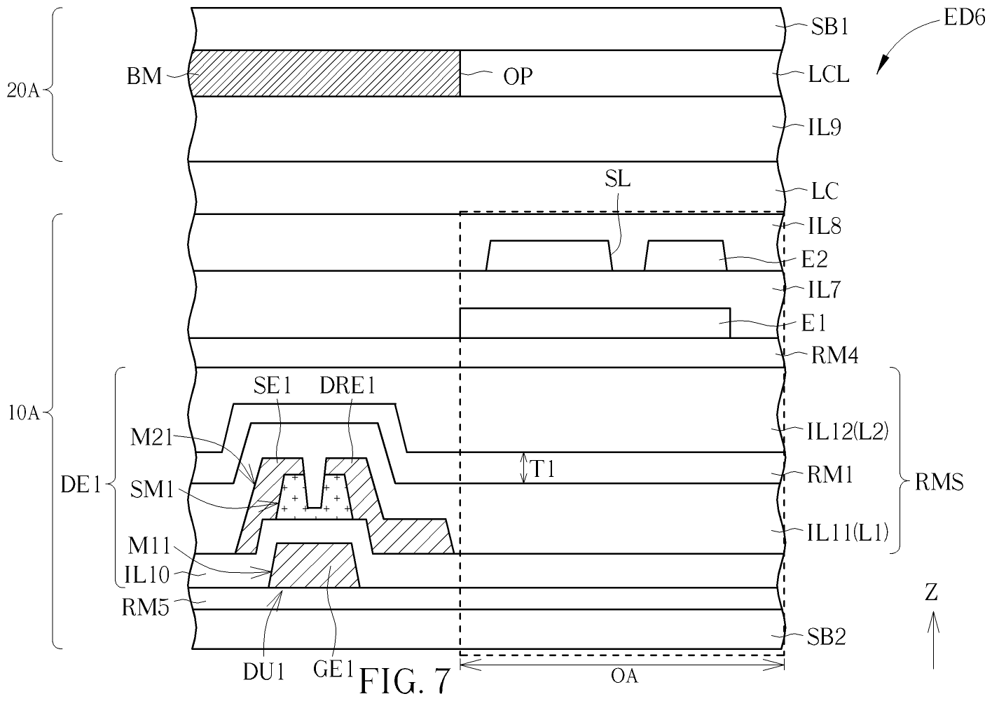

Referring to FIG. 7, FIG. 7 schematically illustrates a cross-sectional view of an electronic device according to a seventh embodiment of the present disclosure. The electronic device ED6 of the present embodiment may include display device, such as non-self-emissive display device, but not limited thereto. In some embodiments, the electronic device ED6 may include self-emissive display device. The liquid crystal display device is taken as an example of the electronic device ED6 for describing the contents of the present embodiment in the following. The features of the layers of the electronic device ED6 located above the driving element DE1 may refer to the above-mentioned contents and FIG. 2, and will not be redundantly described.

According to the present embodiment, the electronic device ED6 may include a fourth refractive index matching layer RM4, wherein the fourth refractive index matching layer RM4 may be disposed on the second layer L2 (that is, the insulating layer IL12) and contact the second layer L2, but not limited thereto. As shown in FIG. 7, the pixel electrode (that is, the electrode E1) may be disposed on the fourth refractive index matching layer RM4. The fourth refractive index matching layer RM4 may be disposed between the second layer L2 and the pixel electrode (that is, the electrode E1). In the present embodiment, the refractive index of the fourth refractive index matching layer RM4 may be in a range between the refractive index of the second layer L2 and the refractive index of the pixel electrode (that is, the electrode E1). For example, the pixel electrode (that is, the electrode E1) may include indium tin oxide, the second layer L2 may include organic photoresist, and the fourth refractive index matching layer RM4 may include the material having the refractive index in a range between the refractive index of organic photoresist and the refractive index of indium tin oxide, such as silicon oxynitride, but not limited thereto. By disposing the fourth refractive index matching layer RM4 between the electrode E1 and the insulating layer IL12 having refractive index difference, the reflectivity of light in the electronic device ED6 may be reduced. The feature of thickness of the fourth refractive index matching layer RM4 may refer to the feature of thickness of the first refractive index matching layer RM1 mentioned above, and will not be redundantly described.

As shown in FIG. 7, the electrode E1 may be the pixel electrode, and the pixel electrode (the electrode E1) may be disposed on the insulating layer IL12. Although it is not shown in the figure, the pixel electrode (the electrode E1) may be electrically connected to the drain electrode DRE1. The insulating layer IL12 may include organic photoresist and may serve as the planarization layer.

According to the present embodiment, the electronic device ED6 may include a fifth refractive index matching layer RM5 disposed between the substrate SB2 and the driving element DE1, but not limited thereto. Specifically, the fifth refractive index matching layer RM5 may be disposed between the substrate SB2 and the gate insulating layer (that is, the insulating layer IL10) of the driving element DE1. The gate insulating layer (the insulating layer IL10) may be disposed between the first conductive layer M11 and the second conductive layer M21. In the present embodiment, the fifth refractive index matching layer RM5 may be disposed between the substrate SB2 and the gate insulating layer (the insulating layer IL10), and the refractive index of the fifth refractive index matching layer RM5 may be in a range between the refractive index of the substrate SB2 and the refractive index of the gate insulating layer (that is, the insulating layer IL10). For example, the substrate SB2 may include glass, the gate insulating layer (that is, the insulating layer IL10) may include silicon nitride, and the fifth refractive index matching layer RM5 may include the material having the refractive index in a range between the refractive index of glass and the refractive index of silicon nitride, such as silicon oxynitride, but not limited thereto. By disposing the fifth refractive index matching layer RM5 between the substrate SB2 and the insulating layer IL10 having refractive index difference, the reflectivity of light in the electronic device ED6 may be reduced. The material and thickness of the fifth refractive index matching layer RM5 may refer to the material and thickness of the first refractive index matching layer RM1 mentioned above, and will not be redundantly described.

It should be noted that the structure of the electronic device ED6 of the present embodiment is not limited to what is shown in FIG. 7. In some embodiments, the electronic device ED6 may include any one of the first refractive index matching layer RM1, the fourth refractive index matching layer RM4 and the fifth refractive index matching layer RM5. In some embodiments, the electronic device ED6 may include any two of the first refractive index matching layer RM1, the fourth refractive index matching layer RM4 and the fifth refractive index matching layer RM5. In some embodiments, the electronic device ED6 may include the first refractive index matching layer RM1, the fourth refractive index matching layer RM4 and the fifth refractive index matching layer RM5.

Table 2 shows the result of the measured reflectivity of the electronic devices of various examples and a comparative example by taking the structure in FIG. 7 as the main structure. The electronic device in the comparative example does not include the first refractive index matching layer RM1, the fourth refractive index matching layer RM4 and the fifth refractive index matching layer RM5. The electronic devices in the example 5, the example 6 and the example 7 respectively include the first refractive index matching layer RM1, the fourth refractive index matching layer RM4 and the fifth refractive index matching layer RM5. The electronic device in the example 8 includes the first refractive index matching layer RM1, the fourth refractive index matching layer RM4 and the fifth refractive index matching layer RM5. The method for measuring the reflectivity may refer to the contents mentioned above, and will not be redundantly described. For example, the array substrate 10A in FIG. 7 may serve as the sample for measuring, and the measurement may be performed at the position in the opening area OA (enclosed by the dotted-line in FIG. 7).

TABLE 2

| | Comparative | Example | Example | Example | Example |
|---|---|---|---|---|---|
| | example 2 | 5 | 6 | 7 | 8 |
| RM1 | X | V | X | X | V |
| RM4 | X | X | V | X | V |
| RM5 | X | X | X | V | V |
| Reflectivity | 2.1 | <2 | <2 | <2 | <1 |
| (%) | | | | | |

“X” represents that the layer does not exist, “V” represents that the layer exists

In the comparative example 2, the reflectivity of light in the electronic device is 2.1%. In the embodiments of the present disclosure, the reflectivity of light in the electronic device may respectively be lower than 2% and even lower than 1%, which is lower than the reflectivity of light in the electronic device in the comparative example 2. It can be seen from table 2 that the reflectivity of light in the electronic device may be reduced by disposing refractive index matching layer (s) in the electronic device, thereby improving the display effect of the electronic device. The refractive index matching layer (s) may for example include the first refractive index matching layer RM1, the fourth refractive index matching layer RM4, the fifth refractive index matching layer RM5 or combinations thereof.

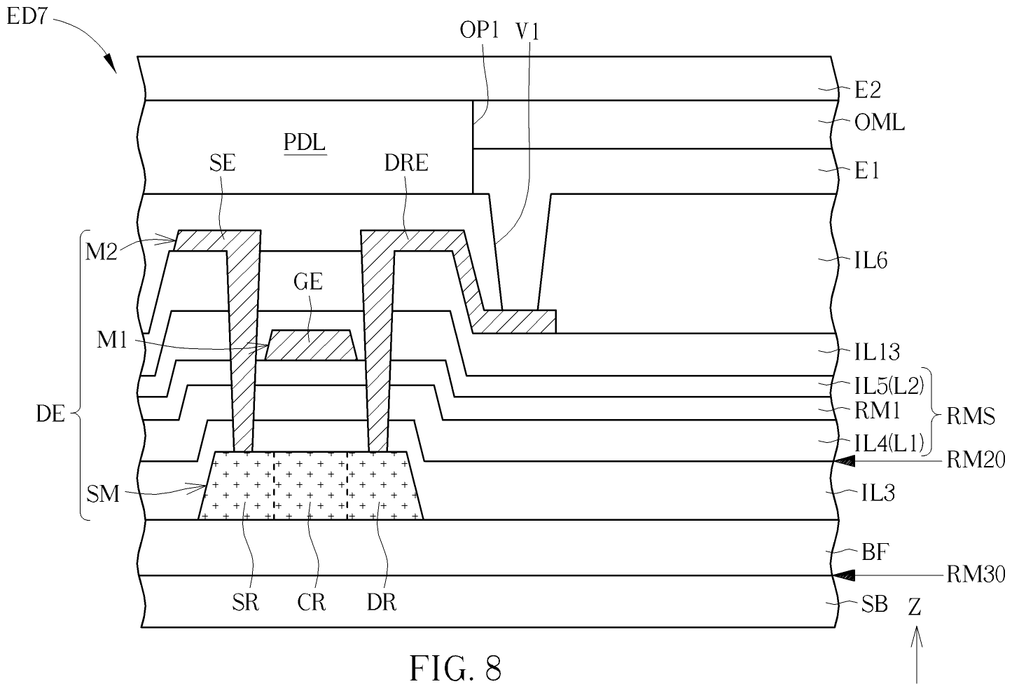

Referring to FIG. 8, FIG. 8 schematically illustrates a cross-sectional view of an electronic device according to an eighth embodiment of the present disclosure. According to the present embodiment, the electronic device ED7 may include organic light emitting diode display. As shown in FIG. 8, the electronic device ED7 may include the substrate SB and the driving element DE disposed on the substrate SB. The driving element DE may include the refractive index matching structure RMS, the refractive index matching structure RMS includes the first layer L1 (the insulating layer IL4), the second layer L2 (the insulating layer IL5) and the first refractive index matching layer RM1, wherein the first refractive index matching layer RM1 is disposed between the first layer L1 and the second layer L2, and the refractive index of the first refractive index matching layer RM1 is in a range between the refractive index of the first layer L1 and the refractive index of the second layer L2. The insulating layer IL6 may be disposed above the driving element DE (for example, above the second conductive layer M2). According to some embodiments, the insulating layer IL6 may include organic photoresist and may serve as the planarization layer.

As shown in FIG. 8, the electronic device ED7 may further include an insulating layer IL13 disposed between the insulating layer IL5 and the insulating layer IL6, and the insulating layer IL13 may include inorganic insulating materials, but not limited thereto. The electronic device ED7 may further include a buffer layer BF disposed between the driving element DE and the substrate SB. The buffer layer BF may include the first buffer layer BF1 and the second buffer layer BF2 mentioned above or combinations thereof. The pixel defining layer PDL is disposed on the insulating layer IL6 (that is, the planarization layer). The pixel defining layer PDL may have openings OP1, wherein the openings OP1 may define the light emitting region of the electronic device ED7. The electronic device ED7 may include the electrode E1, the organic light emitting layer OML and the electrode E2. The electrode E1 may be disposed in the opening OP1 of the pixel defining layer PDL. The organic light emitting layer OML is disposed between the electrode E1 and the electrode E2. The electrode E1 may be the anode, and the electrode E2 may be the cathode. The electrode E1 may be disposed above the driving element DE and may be electrically connected to the drain electrode DRE through the via V1 penetrating the insulating layer IL6.

The electronic device ED7 shown in FIG. 8 includes the first refractive index matching layer RM1 disposed below the first conductive layer M1 and located between the semiconductor layer SM and the first conductive layer M1. However, the structure of the electronic device ED7 of the present embodiment is not limited to what is shown in FIG. 8. According to some embodiments, although it is not shown in FIG. 8, the electronic device ED7 may include the refractive index matching layer (s) at other positions. For example, in some embodiments, the electronic device ED7 may include a second refractive index matching layer RM20 disposed between the insulating layer IL3 and the insulating layer IL4, which is shown as an arrow in FIG. 8, but not limited thereto. For example, in some embodiments, the electronic device ED7 may include a third refractive index matching layer RM30 disposed between the substrate SB and the buffer layer BF, which is shown as an arrow in FIG. 8, but not limited thereto. In some embodiments, the electronic device ED7 may include any one of the first refractive index matching layer RM1, the second refractive index matching layer RM20 and the third refractive index matching layer RM30. In some embodiments, the electronic device ED7 may include any two of the first refractive index matching layer RM1, the second refractive index matching layer RM20 and the third refractive index matching layer RM30. In some embodiments, the electronic device ED7 may include the first refractive index matching layer RM1, the second refractive index matching layer RM20 and the third refractive index matching layer RM30.

In summary, an electronic device is provided by the present disclosure, wherein the driving element of the electronic device may include the refractive index matching structure, or the refractive index matching structure may be disposed in the driving element. Therefore, the reflectivity of light in the electronic device may be reduced by disposing the refractive index matching layer, thereby improving the display effect of the electronic device.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a substrate; and
a driving element disposed on the substrate, the driving element comprising a refractive index matching structure, the refractive index matching structure comprising a first layer, a second layer and a first refractive index matching layer, wherein the first refractive index matching layer is disposed between the first layer and the second layer, and a refractive index of the first refractive index matching layer is in a range between a refractive index of the first layer and a refractive index of the second layer.

2. The electronic device of claim 1, wherein the driving element comprises:
a first conductive layer comprising a gate electrode; and
a second conductive layer comprising a drain electrode,
wherein the refractive index matching structure is disposed between the first conductive layer and the second conductive layer.

3. The electronic device of claim 2, wherein the electronic device further comprises:
a planarization layer disposed on the second conductive layer;
a pixel electrode disposed on the planarization layer and electrically connected to the drain electrode; and
a second refractive index matching layer disposed between the planarization layer and the pixel electrode,
wherein a refractive index of the second refractive index matching layer is in a range between a refractive index of the planarization layer and a refractive index of the pixel electrode.

4. The electronic device of claim 3, wherein the planarization layer comprises organic photoresist, and the pixel electrode comprises indium tin oxide.

5. The electronic device of claim 3, wherein the second refractive index matching layer comprises silicon oxynitride.

6. The electronic device of claim 2, wherein the electronic device further comprises:
a third refractive index matching layer disposed on the substrate; and
a buffer layer disposed between the third refractive index matching layer and the driving element,
wherein a refractive index of the third refractive index matching layer is in a range between a refractive index of the substrate and a refractive index of the buffer layer.

7. The electronic device of claim 6, wherein the buffer layer comprises silicon oxide or silicon nitride.

8. The electronic device of claim 2, wherein the electronic device further comprises:
a first buffer layer disposed on the substrate;
a third refractive index matching layer disposed on the first buffer layer; and
a second buffer layer disposed between the third refractive index matching layer and the driving element,
wherein a refractive index of the third refractive index matching layer is in a range between a refractive index of the first buffer layer and a refractive index of the second buffer layer.

9. The electronic device of claim 8, wherein the first buffer layer comprises silicon nitride, and the second buffer layer comprises silicon oxide.

10. The electronic device of claim 1, further comprising a second buffer layer disposed between the substrate and the driving element, wherein the second buffer layer directly contacts the substrate, and a thickness of the second buffer layer ranges from 200 angstroms to 6000 angstroms.

11. The electronic device of claim 10, wherein the thickness of the second buffer layer ranges from 2000 angstroms to 6000 angstroms.

12. The electronic device of claim 1, wherein the driving element comprises:
a first conductive layer comprising a gate electrode; and
a second conductive layer comprising a drain electrode,
wherein the second conductive layer is disposed on the first conductive layer, and the refractive index matching structure is disposed on the second conductive layer.

13. The electronic device of claim 12, wherein the electronic device further comprises:
a fourth refractive index matching layer disposed on the second layer; and
a pixel electrode disposed on the fourth refractive index matching layer;
wherein a refractive index of the fourth refractive index matching layer is in a range between a refractive index of the second layer and a refractive index of the pixel electrode.

14. The electronic device of claim 12, wherein the driving element comprises a gate insulating layer disposed between the first conductive layer and the second conductive layer, the electronic device further comprising:
a fifth refractive index matching layer disposed between the substrate and the gate insulating layer, wherein a refractive index of the fifth refractive index matching layer is in a range between a refractive index of the substrate and a refractive index of the gate insulating layer.

15. The electronic device of claim 1, wherein the first refractive index matching layer comprises silicon oxynitride, silicon oxide, silicon nitride, magnesium fluoride, calcium fluoride, barium fluoride, lanthanum fluoride, or combination thereof.

16. The electronic device of claim 1, wherein a thickness of the first refractive index matching layer ranges from 200 angstroms to 4000 angstroms.

17. The electronic device of claim 16, wherein the thickness of the first refractive index matching layer ranges from 200 angstroms to 3000 angstroms.

18. The electronic device of claim 1, wherein the electronic device further comprises a third conductive layer disposed on the substrate, wherein the third conductive layer forms a light shielding element.

19. The electronic device of claim 18, wherein the driving element further comprises a semiconductor layer, and the third conductive layer at least partially overlaps the semiconductor layer.

20. The electronic device of claim 1, wherein the driving element comprises a thin film transistor.
